(19) United States
(12) Patent Application Publication
(10) Pub. No.: US 2018/0366476 A1
(43) Pub. Date: Dec. 20, 2018

(54) FERROELECTRIC FIELD EFFECT TRANSISTOR, FERROELECTRIC MEMORY AND DATA READING/WRITING METHOD AND MANUFACTURING METHOD THEREOF

(71) Applicant: NuStorage Technology Co., Ltd., Apia (WS)

(72) Inventor: FU-CHOU LIU, Hsin-Chu County (TW)

(21) Appl. No.: 15/914,079

(22) Filed: Mar. 7, 2018

(30) Foreign Application Priority Data
Jun. 14, 2017 (CN) 201710448831.9

(51) Int. Cl. H01L 27/1159; H01L 29/78; G11C 11/22; H01L 29/66; H01L 21/28; H01L 29/51

(52) U.S. Cl. CPC H01L 27/1159; H01L 29/78391; G11C 11/2275; G11C 11/2273; H01L 29/6684; H01L 21/02181; G11C 11/223; H01L 29/516; H01L 29/513; H01L 29/517; H01L 21/28291

(57) ABSTRACT

A ferroelectric field effect transistor is provided. Within the ferroelectric field effect transistor, a semiconductor substrate, a dielectric layer, a polarity retention layer and a conductive layer are sequentially fabricated. The polarity retention layer includes a ferroelectric layer and an anti-ferroelectric layer. By switching directions of electric dipoles in the ferroelectric layer, the operation speed of the memory including the ferroelectric field effect transistor is increased. A ferroelectric memory and a data writing method, a data reading method and a manufacturing method thereof are also provided.

### TECHNICAL FIELD

The disclosure relates to the technical area of field effect transistors, and particularly to a ferroelectric field effect transistor, a ferroelectric memory including the ferroelectric field effect transistor, a data reading method of the ferroelectric memory, a data writing method of the ferroelectric memory and a manufacturing method of the ferroelectric memory.

### BACKGROUND

As shown in FIG. 1A and FIG. 1B, a ferroelectric field effect transistor (FeFET) 10 is a metal oxide semiconductor (MOS) transistor including a gate 12, a ferroelectric layer 14, a source 16 and a drain 18. A channel CH is formed between the source 16 and the drain 18 when a specific voltage is applied to the gate 12. Moreover, in order to prevent charges in the channel CH from diffusing into the ferroelectric layer 14, usually a dielectric layer 15 may be disposed between the channel CH and the ferroelectric layer 14.

In actual operation, electric potential differences among the gate 12, the source 16 and the drain 18 are utilized to make the ferroelectric layer 14 generate electric dipoles D in response to influence of electric fields. Therefore, when the electric potentials of the source 16 and the drain 18 are fixed, the polarization directions of the electric dipoles D vary with the electric potential of the gate 12. Further, the polarization directions of the electric dipoles D directly determine the type of majority carriers in the channel CH. For example, provided that the electric potentials of the source 16 and the drain 18 are both null in FIGS. 1A and 1B, the electric potential applied to the gate 12 in FIG. 1A is a positive potential +V, and the electric potential applied to the gate 12 in FIG. 1B is a negative potential −V, then the electric dipoles D in FIG. 1A appear with negative poles being closer to the gate 12 and positive poles being closer to the channel CH, and the electric dipoles D in FIG. 1B appear with positive poles being closer to the gate 12 and negative poles being closer to the channel CH. Therefore, the majority carriers in the channel CH in FIG. 1A are electrons because of attraction by the positive poles of the electric dipoles D. On the contrary, the majority carriers in the channel CH in FIG. 1B are holes because of attraction by the negative poles of the electric dipoles D.

The transistors shown in FIGS. 1A and 1B are n-type transistors. When the positive potential +V is applied to the gate 12 in FIG. 1A to make the majority carriers in the channel CH be electrons, the threshold voltage of the FeFET 10 is lowered so that the source 16 and the drain 18 can be electrically connected to each other comparatively easily through the channel CH. On the contrary, when the negative potential −V is applied to the gate 12 in FIG. 1B to make the majority carriers in the channel CH be holes, the threshold voltage of the FeFET 10 is raised so that it is more difficult to electrically connect the source 16 and the drain 18 through the channel CH. The levels of the threshold voltage can be used as different data stored in a memory.

In some references, the idea of applying a FeFET to a dynamic random-access memory has been proposed, e.g. in U.S. Pat. No. 6,067,244. However, there are many drawbacks in the techniques addressed by the references. One of the drawbacks is that it is difficult to synthesize the ferroelectric material and a Si substrate. Furthermore, some ferroelectric materials also require thicker ferroelectric layers (e.g. greater than 200 nm) for enabling desired characteristics. Therefore, it is very hard for current techniques to scale down the FeFETs, fabrication processes of the FeFETs are also difficult, and cost of the FeFETs is high. Although ferroelectric materials doped with hafnium dioxide (HfO₂) is proposed to scale down the FeFETs in recent references, the HfO₂ concentration is extremely low (about 3-5%), and it is difficult to control the doping uniformity across the wafer.

From another perspective, the data stored in the FeFET may be easily affected when the FeFET is biased with one half of a programming voltage Vpp (the programming voltage Vpp represents the voltage required for programming a memory cell). One current solution is proposed as follows. During program operation (e.g. write “1”), unselected memory cells connected to the selected word line (WL) or the selected bit line (BL) are biased to ⅔ Vpp, and other unselected word lines are biased to ⅓ Vpp. During erase operation (e.g. write “0”), unselected memory cells connected to the selected word line or the selected bit line are biased to ⅓ Vpp, and other unselected word lines are biased to ⅔ Vpp. This method can reduce possibility of affecting the data stored in the memory cells.

Nevertheless, there are still drawbacks in above data writing method. For example, when switching among the program operation, the erase operation and the read operation is being implemented, it is necessary to properly transform electric potentials of the bit lines and the word lines. However, the time required for transforming electric potentials will seriously affect switching speed among each of the operations.

Therefore, in summary, lots of drawbacks still exist in the current techniques. To the area of ferroelectric technology, a new ferroelectric material, a manufacturing method of the new ferroelectric material, a new FeFET, a new ferroelectric memory structure and the operation method thereof become objects which all parties are actively studying.

### SUMMARY

The disclosure provides a ferroelectric field effect transistor, a ferroelectric memory, a data reading method of the ferroelectric memory, a data writing method of the ferroelectric memory and a manufacturing method of the ferroelectric memory, so as to light up a new direction of development in the area of ferroelectric technology.

An aspect of the disclosure provides a ferroelectric field effect transistor (FeFET). The FeFET includes a semiconductor substrate, a first doped region, a second doped region, a dielectric layer, a polarity retention layer and a conductive layer. The semiconductor substrate has an upper surface, and is made of a semiconductor material and doped with a material of a first conductivity type. The first doped region and the second doped region are formed in the semiconductor substrate and have a material of a second conductivity type. The second doped region is separated from the first doped region. The dielectric layer is disposed on and in contact with the upper surface of the semiconductor substrate. The polarity retention layer includes a ferroelectric layer and an anti-ferroelectric layer. The polarity retention layer and the semiconductor substrate are disposed on opposite surfaces of the dielectric layer. The conductive layer and the dielectric layer are disposed on opposite surfaces of the polarity retention layer.

Another aspect of the disclosure provides a ferroelectric memory. The ferroelectric memory includes a plurality of memory cells, each of which is electrically connected to a bit-write line, a bit-read line, a word line and a plate line. Each memory cell includes a non-ferroelectric field effect transistor (FET) and a FeFET. The non-ferroelectric FET includes a non-ferroelectric control terminal, a first non-ferroelectric access terminal and a second non-ferroelectric access terminal. The non-ferroelectric control terminal is electrically connected to the word line; and the first non-ferroelectric access terminal is electrically connected to the bit-write line. The FeFET includes a ferroelectric control terminal, a first ferroelectric access terminal and a second ferroelectric access terminal. The ferroelectric control terminal is electrically connected to the second non-ferroelectric access terminal; the first ferroelectric access terminal is electrically connected to the bit-read line; and the second ferroelectric access terminal is electrically connected to the plate line.

Another aspect of the disclosure provides a data writing method adapted to be implemented in the ferroelectric memory. The data writing method includes steps of: supplying a first voltage which represents data to be written into the memory cell to the bit-write line; supplying a second voltage to the bit-read line; supplying the second voltage to the plate line; and supplying a third voltage to the word line. The third voltage is sufficient to turn on the non-ferroelectric FET. A difference between the first voltage and the second voltage is sufficient to program the FeFET.

Another aspect of the disclosure provides a data reading method adapted to be implemented in the ferroelectric memory. The data reading method includes steps of: supplying a first voltage to the bit-write line; supplying a second voltage to the plate line; supplying a third voltage to the word line; and acquiring a voltage level from the bit-read line for serving as data stored in the memory cell. The third voltage is sufficient to turn on the non-ferroelectric FET. An absolute value of the first voltage is greater than an absolute value of the second voltage.

Another aspect of the disclosure provides a manufacturing method of a ferroelectric memory including a non-ferroelectric FET and a FeFET. The manufacturing method includes the following steps. A semiconductor substrate made of a semiconductor material and doped with a material of a first conductivity type is provided. A first dielectric layer and a word line are formed on a first area of the semiconductor substrate. A second dielectric layer, a polarity retention layer and a control electrode are formed on a second area of the semiconductor substrate. A first doped region, a second doped region, a third doped region and a fourth region are formed by doping a material of a second conductivity type into the semiconductor substrate by using the word line and the control electrode as a mask. The first doped region and the second doped region are adjacent to the first area. The third doped region and the fourth doped region are adjacent to the second area. The non-ferroelectric FET includes the first dielectric layer, the word line, the first doped region, the second doped region and the first area of the semiconductor substrate, and the FeFET includes the second dielectric layer, the polarity retention layer, the control electrode, the third doped region, the fourth doped region and the second area of the semiconductor substrate. A first interconnect, a second interconnect, a third interconnect, a fourth interconnect and an electrode interconnect are respectively formed on and electrically connected to the first doped region, the second doped region, the third doped region, the fourth doped region and the control electrode. A plate electrically connected to the electrode interconnect and the second interconnect is formed. A plate line electrically connected to the fourth interconnect is formed. A bit-write line electrically connected to the first interconnect is formed. A bit-read line electrically connected to the third interconnect is formed.

### BRIEF DESCRIPTION OF THE DRAWINGS

The advantages of the disclosure will become more readily apparent to those ordinarily skilled in the art after reviewing the following detailed description and accompanying drawings, in which:

FIG. 1A is a schematic diagram illustrating the structure of the conventional FeFET and the electric dipole arrangement wherein a positive potential is applied on the gate of the FeFET;

FIG. 1B is a schematic diagram illustrating the structure of the conventional FeFET and the electric dipole arrangement wherein a negative potential is applied on the gate terminal;

FIG. 2A is a schematic diagram illustrating the structure of a FeFET according to an embodiment of the disclosure;

FIG. 2B is a schematic diagram illustrating the structure of a FeFET according to another embodiment of the disclosure;

FIG. 3A is a schematic diagram illustrating the structure of a FeFET according to a further embodiment of the disclosure;

FIG. 3B is a schematic diagram illustrating the structure of a FeFET according to a further embodiment of the disclosure;

FIG. 4 is a circuit diagram illustrating a portion of an array structure in a ferroelectric memory according to an embodiment of the disclosure;

FIG. 5 is a flowchart illustrating a data writing method of the ferroelectric memory of FIG. 4;

FIG. 6 is a flowchart illustrating a data reading method of the ferroelectric memory of FIG. 4;

FIG. 7 is a circuit diagram illustrating a portion of an array structure in a ferroelectric memory according to another embodiment of the disclosure;

FIG. 8 is a schematic diagram illustrating the composition of the ferroelectric layer according to an embodiment of the disclosure;

FIG. 9 is a schematic diagram illustrating the composition of the ferroelectric layer according to another embodiment of the disclosure;

FIG. 10A and FIG. 10B are schematic diagrams illustrating the composition of the ferroelectric layers according to further embodiments of the disclosure;

FIG. 11A˜FIG. 11E are schematic diagrams illustrating a manufacturing method of the ferroelectric memory according an embodiment of the disclosure;

FIG. 12A and FIG. 12B are top views illustrating a portion of an array structure corresponding to FIG. 11B and FIG. 11D, respectively;

FIG. 13 is a top view showing FeFETs and non-ferroelectric FETs in a portion of an array structure according to an embodiment of the disclosure;

FIG. 14A and FIG. 14B are schematic diagrams illustrating a manufacturing method of the ferroelectric memory according to another embodiment of the disclosure; and

FIG. 15A and FIG. 15B are top views illustrating a portion of an array structure corresponding to FIG. 11B and FIG. 14A, respectively.

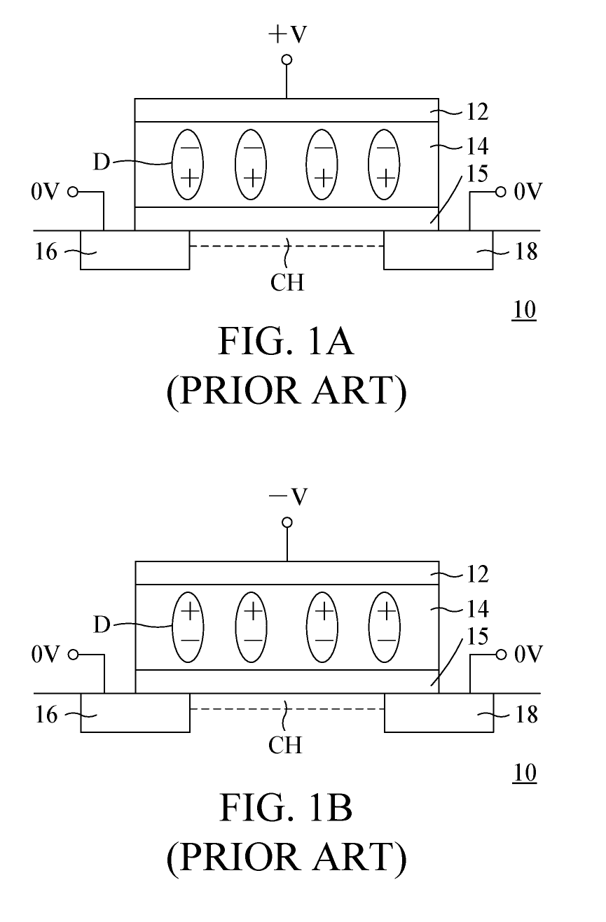

### DETAILED DESCRIPTION OF PREFERRED EMBODIMENTS

The disclosure will now be described more specifically with reference to the following embodiments. It is to be noted that the following descriptions of preferred embodiments of this invention are presented herein for purpose of illustration and description only. It is not intended to be exhaustive or to be limited to the precise form disclosed.

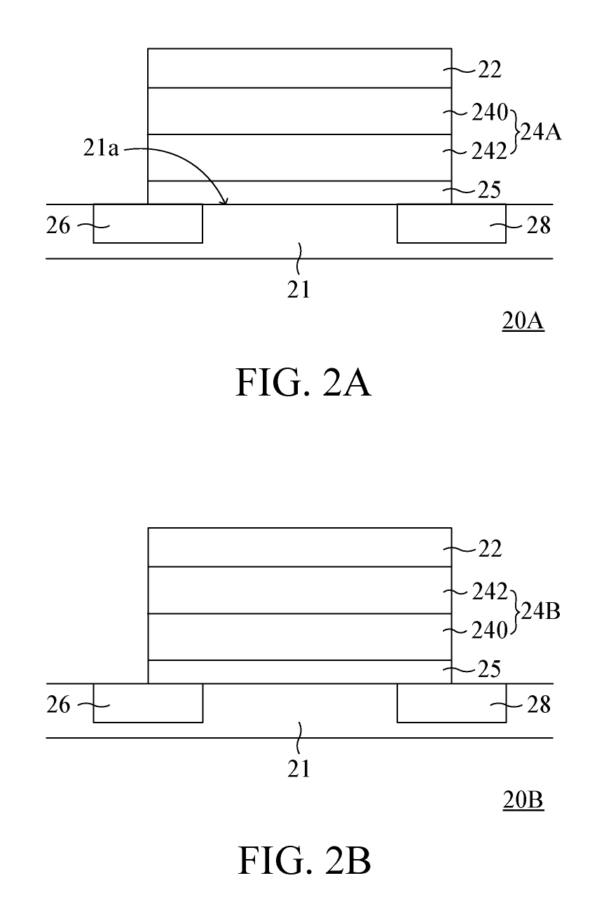

Please refer to FIG. 2A, a schematic diagram illustrating the structure of a FeFET according to an embodiment of the disclosure. The FeFET 20A includes a semiconductor substrate 21, a first doped region 26, a second doped region 28, a dielectric layer 25, a polarity retention layer 24A and a conductive layer 22. The semiconductor substrate 21 is made of a semiconductor material and doped with a material of a first conductivity type. The first doped region 26 and the second doped region 28 are formed in the semiconductor substrate 21 and doped with a material of a second conductivity type. The first doped region 26 and the second doped region 28 are separated from each other. The dielectric layer 25 is disposed on and in contact with an upper surface 21a of the semiconductor substrate 21. The dielectric layer 25 covers a portion of the first doped region 26 and a portion of the second doped region 28. It is to be noted that the dielectric layer 25 may overlap the first doped region 26 and the second doped region 28 or may not according to different applications. The polarity retention layer 24A and the semiconductor substrate 21 are disposed on opposite surfaces of the dielectric layer 25. The polarity retention layer 24A includes a ferroelectric layer 240 and an anti-ferroelectric layer 242. The conductive layer 22 and the dielectric layer 25 are disposed on opposite surfaces of the polarity retention layer 24A. In this embodiment, the anti-ferroelectric layer 242 is disposed on and in contact with the dielectric layer 25, while the ferroelectric layer 240 is disposed on the anti-ferroelectric layer 242 and in contact with the anti-ferroelectric layer 242 and the conductive layer 22.

The combination of the ferroelectric layer 240 and the anti-ferroelectric layer 242 can speed up operation of the FeFET 20A because electric dipoles formed in the ferroelectric layer 240 can continuously help trapping charges after the ferroelectric layer 240 is polarized. For example, a voltage is temporarily applied on the FeFET until polarization of the electric dipoles in the ferroelectric layer 240 is formed. Even though the FeFET 20A has not been switched completely (i.e. switching from ON state to OFF state or from OFF state to ON state), the circuit may turn to operate another FeFET. And after the circuit turned to operate another FeFET, the previously operated FeFET may still continuously use the electric dipoles in the ferroelectric layer 240 to trap charges in the anti-ferroelectric layer 242. Therefore, the state of the FeFET 20A is ultimately changed. Because switching speed of the electric dipoles is much higher than that of the FeFET, such structure can effectively speed up operation speed of the whole FeFET circuit.

Please refer to FIG. 2B, a schematic diagram illustrating the structure of a FeFET according to another embodiment of the disclosure. The FeFET 20B includes a semiconductor substrate 21, a first doped region 26, a second doped region 28, a dielectric layer 25, a polarity retention layer 24B and a conductive layer 22. The main difference between the FeFET 20B and the FeFET 20A is that the structure of the polarity retention layer 24B differs from the structure of the polarity retention layer 24A. In the embodiment of FIG. 2B, the ferroelectric layer 240 is disposed on and in contact with the dielectric layer 25, while the anti-ferroelectric layer 242 is disposed on the ferroelectric layer 240 and in contact with the ferroelectric layer 240 and the conductive layer 22. Except for the above distinction, the FeFET 20B is roughly the same as the FeFET 20A, and repetitious details are not given here.

In another design, a charge blocking layer may be further introduced into the polarity retention layer 24A or 24B.

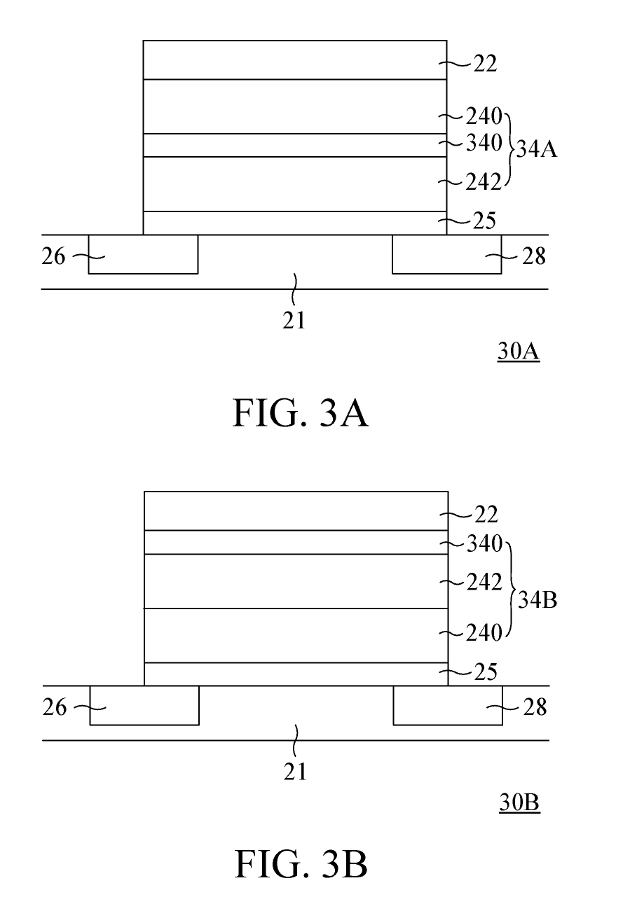

Please refer to FIG. 3A, a schematic diagram illustrating the structure of a FeFET according to a further embodiment of the disclosure. The FeFET 30A includes a semiconductor substrate 21, a first doped region 26, a second doped region 28, a dielectric layer 25, a polarity retention layer 34A and a conductive layer 22. The main difference between the FeFET 30A and the FeFET 20A in FIG. 2A is that the structure of the polarity retention layer 34A differs from the structure of the polarity retention layer 24A. The polarity retention layer 34A, similar to the polarity retention layer 24A, includes a ferroelectric layer 240 and an anti-ferroelectric layer 242. In addition, the polarity retention layer 34A further includes a charge blocking layer 340. In this embodiment, the anti-ferroelectric layer 242 is disposed between the dielectric layer 25 and the charge blocking layer 340. The charge blocking layer 340 is disposed between the anti-ferroelectric layer 242 and the ferroelectric layer 240. Two opposite surfaces of the charge blocking layer 340 are in contact with the anti-ferroelectric layer 242 and the ferroelectric layer 240, respectively. Thus, the charge blocking layer 340 can prevent the charged particles in the anti-ferroelectric layer 242 from entering the ferroelectric layer 240 so as to keep the ferroelectric characteristics of the ferroelectric layer 240. Except for the above distinction, the FeFET 30A is roughly the same as the FeFET 20A, and repetitious details are not given here.

Please refer to FIG. 3B, a schematic diagram illustrating the structure of a FeFET according to a further embodiment of the disclosure. The FeFET 30B includes a semiconductor substrate 21, a first doped region 26, a second doped region 28, a dielectric layer 25, a polarity retention layer 34B and a conductive layer 22. The main difference between the FeFET 30B and the FeFET 30A in FIG. 3A is that the structure of the polarity retention layer 34B differs from the structure of the polarity retention layer 34A. In this embodiment, the polarity retention layer 34B identically includes a ferroelectric layer 240, an anti-ferroelectric layer 242 and a charge blocking layer 340, but the relative positions are altered. The ferroelectric layer 240 is disposed on and in contact with the dielectric layer 25. The anti-ferroelectric layer 242 is disposed on the ferroelectric layer 240, and two opposite surfaces of the anti-ferroelectric layer 242 are in contact with the ferroelectric layer 240 and the charge blocking layer 340, respectively. The charge blocking layer 340 is disposed on the anti-ferroelectric layer 242, and two opposite surfaces of the charge blocking layer 340 are in contact with the anti-ferroelectric layer 242 and the conductive layer 22, respectively. The charge blocking layer 340 can prevent the charges in the conductive layer 22 from entering the anti-ferroelectric layer 242 so that the charged particles in the conductive layer 22 can't enter into the ferroelectric layer 240 through the anti-ferroelectric layer 242. Such design can keep the ferroelectric characteristics of the ferroelectric layer 240. Except for the above difference, the FeFET 30B is roughly the same as the FeFET 30A, and repetitious details are not given here.

In the above-described embodiments or the following embodiments, the charge blocking layer may be made of silicon dioxide (SiO₂), silicon nitride (Si₃N₄), aluminum oxide (Al₂O₃), hafnium dioxide (HfO₂) or oxide-nitride-oxide (ONO). ONO is a complex formed with a triple-layer material, specifically consisting of, e.g. SiO₂/Si₃N₄/SiO₂.

In the above-described embodiments or the following embodiments, the ferroelectric layer may be made of Hf_{0.8x}Si_{0.2x}Zr₍₁₋ₓ₎O_{y} ferroelectric material, Hf_{0.9x}Si_{0.1x}Zr₍₁₋ₓ₎O_{y} ferroelectric material, Hf_{0.95x}Si_{0.05x}Zr₍₁₋ₓ₎O_{y} ferroelectric material or HfₓZr₍₁₋ₓ₎O_{y} ferroelectric material doped with aluminum (Al), silicon (Si), titanium (Ti) or tantalum (Ta). The x value ranges from 0.25 to 0.75, and the y value ranges from 1.8 to 2.2. In another embodiment, the x value ranges from 0.4 to 0.6, and the y value ranges from 1.9 to 2.1. In addition, HfO₂ ferroelectric material doped with Si, Al, gadolinium (Gd), lanthanum (La), yttrium (Y) or strontium (Sr) is also applicable.

In the above-described embodiments or the following embodiments, the anti-ferroelectric layer may be made of Hf₍₁₋ₓ₎SiₓO₂ or Hf₍₁₋ₓ₎AlₓO₂, wherein the x value ranges from 0.07 to 0.15.

In the above-described embodiments or the following embodiments, the dielectric layer may be made of SiO₂ or silicon oxynitride (SiON).

In the above-described embodiments or the following embodiments, the conductive layer may be made of titanium nitride (TiN), tantalum nitride (TaN), tungsten nitride (WN), wolfram (W), iridium (Ir), ruthenium (Ru), ruthenium oxide (RuOₓ), platinum (Pt), palladium (Pd) or other conductive material.

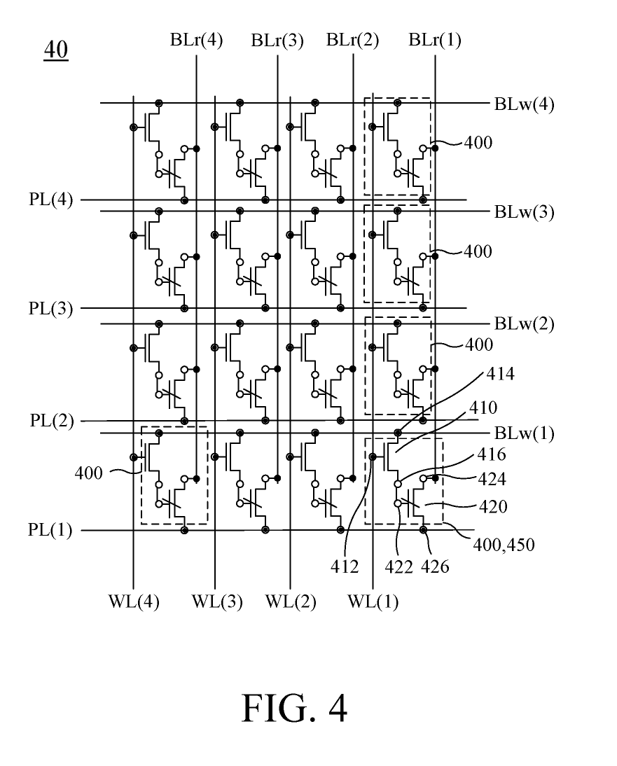

Please refer to FIG. 4, a circuit diagram illustrating a portion of an array structure in a ferroelectric memory according to an embodiment of the disclosure. As shown in FIG. 4, the ferroelectric memory 40 includes a plurality of memory cells 400, at least one bit-write line (e.g. BLw(1)˜BLw(4)), at least one bit-read line (e.g. BLr(1)˜BLr(4)), at least one word line (e.g. WL(1)˜WL(4)) and at least one plate line (e.g. PL(1)˜PL(4)). Each memory cell 400 is electrically connected to one of the bit-write lines, one of the bit-read lines, one of the word lines and one of the plate lines.

Taking the lower right memory cell 450 in FIG. 4 (called selected memory cell 450 hereinafter) as an example, the selected memory cell 450 includes a non-ferroelectric FET 410 and a FeFET 420. The non-ferroelectric FET 410 includes a non-ferroelectric control terminal 412 and two non-ferroelectric access terminals 414 and 416, while the FeFET 420 includes a ferroelectric control terminal 422 and two ferroelectric access terminals 424 and 426. The non-ferroelectric control terminal 412 is electrically connected to the word line WL(1), the non-ferroelectric access terminal 414 is electrically connected to the bit-write line BLw(1), the ferroelectric control terminal 422 is electrically connected to the non-ferroelectric access terminal 416, the ferroelectric access terminal 424 is electrically connected to the bit-read line BLr(1), and the ferroelectric access terminal 426 is electrically connected to the plate line PL(1).

It is to be noted that the term “non-ferroelectric FET” means a transistor in which no ferroelectric material is used, and the term “FeFET” means a transistor using a ferroelectric material which is not limited to the ferroelectric materials described in the embodiments of the disclosure. In other words, the FeFET used in the ferroelectric memory 40 may be a known FeFET and is not limited to the FeFET described in the embodiments of the disclosure.

Then, identically taking the selected memory cell 450 as an example, a data writing method and a data reading method of the above-described ferroelectric memory 40 are described in the following paragraphs.

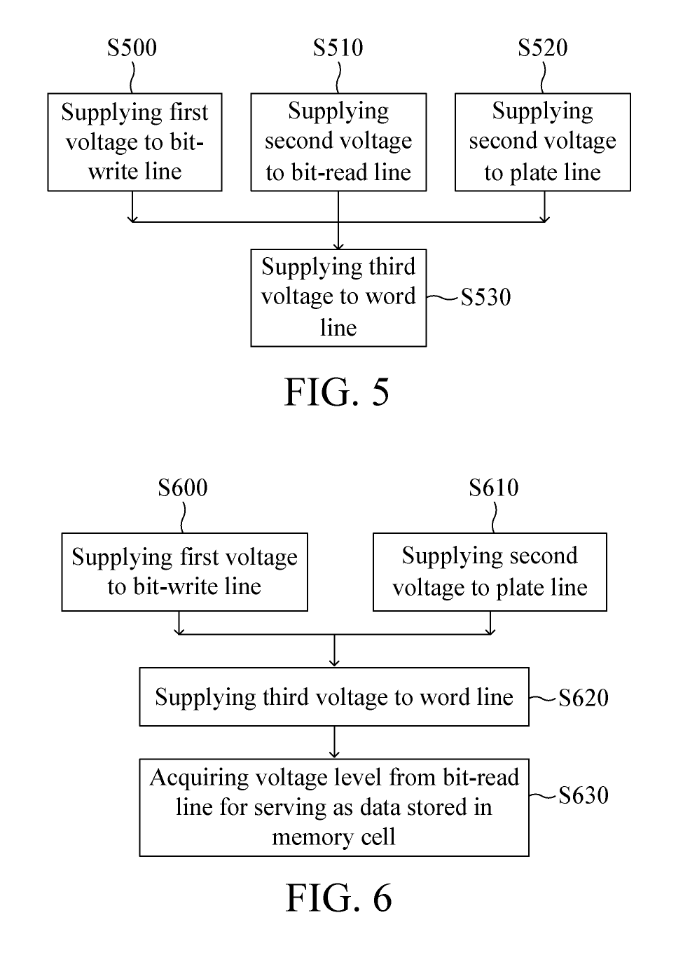

Please refer to both FIG. 4 and FIG. 5, wherein FIG. 5 is a flowchart illustrating a data writing method of the ferroelectric memory according to an embodiment of the disclosure. The selected memory cell 450 is taken as an example. At first, a first voltage is supplied to the bit-write line BLw(1) (step S500), and a second voltage is supplied to the bit-read line BLr(1) (step S510), and the second voltage is supplied to the plate line PL(1) (step S520). The first voltage represents the data to be stored in the selected memory cell 450. That is, when the data to be stored in the selected memory cell 450 is “1”, the first voltage is a specific value, and when the data to be stored in the selected memory cell 450 is “0”, the first voltage is another specific value, wherein the two specific values are different. The second voltage is a fixed value, and the difference between the first voltage and the second voltage should be greater enough to program the FeFET 420. For example, given that the minimum value of the voltage difference required for programming the FeFET 420 is a programming voltage Vpp, the difference between the first voltage and the second voltage should be at least equal to the programming voltage Vpp. To minimize diversity of power sources, the difference between the first voltage and the second voltage is set to be equal to or slightly greater than the programming voltage Vpp to ensure smooth operation of the circuit.

In practical operation, the second voltage may be ⅓ Vpp, and the previously mentioned specific values of the first voltage may respectively be 4/3 Vpp and −⅔ Vpp according to different data to be written into the memory cell 450. In another embodiment, the second voltage may be zero, and the previously mentioned specific values of the first voltage may respectively be Vpp and −Vpp according to different data to be written into the memory cell 450.

Then, a third voltage is supplied to the word line WL(1) (step S530) after the above steps have been done. The third voltage should be sufficient to switch on the non-ferroelectric FET 410.

In the selected memory cell 450, when the third voltage is supplied to the word line WL(1), the third voltage is applied to the non-ferroelectric control terminal 412. Therefore, the non-ferroelectric FET 410 is switched on so as to conduct the path between the non-ferroelectric access terminal 414 and the non-ferroelectric access terminal 416. At this time, the first voltage applied to the bit-write line BLw(1) is supplied to the ferroelectric control terminal 422 via the electrical path between the non-ferroelectric access terminal 414 and the non-ferroelectric access terminal 416. Because the second voltage has been supplied to the bit-read line BLr(1) and the plate line PL(1), the FeFET 420 is biased with the voltage equal to the difference between the first voltage and the second voltage, i.e. the voltage sufficient to program the FeFET 420. Therefore, once the third voltage is supplied to the word line WL(1), the data starts to be written into the selected memory cell 450.

In this embodiment, all of the bit-read lines BLr(1)˜BLr(4), all of the plate lines PL(1)˜PL(4) and the bit-write lines BLw(2)˜BLw(4) not written with data are biased with the second voltage (e.g. ⅓ Vpp or zero voltage). Besides, the voltage of the word lines WL(2)˜WL(4) is at a level insufficient to switch on the non-ferroelectric FETs 410. Thus, the data stored in the memory cells 400 connected to the word lines WL(2)˜WL(4) will not be affected because the environment is steadily stayed at a stable condition (other non-ferroelectric FETs 410 are at OFF states). Except for the selected memory cell 450, as to the memory cells 400 identically connected to the WL(1), though the non-ferroelectric FETs are switched on, the voltages of the corresponding bit-write lines BLw(2)˜BLw(4) are exactly the same as the aforementioned second voltage. Therefore, the data stored in the FeFETs not selected are unaffected since the potentials of the three terminals (i.e. one ferroelectric control terminal and two ferroelectric access terminals) of the FeFET of each unselected memory cell 400 are equal.

The sequence of the steps S500˜S530 is not limited to that as shown in FIG. 5. The sequence may be modified to meet the above-described principle without departing from the scope of the disclosure.

Please refer to both FIG. 4 and FIG. 6, wherein FIG. 6 is a flowchart illustrating a data reading method of the ferroelectric memory according to an embodiment of the disclosure. It is to be noted that although the same terms “first voltage”, “second voltage” and “third voltage” are used in the description, but FIG. 5 and FIG. 6 show different operations. The definitions of the first voltage, the second voltage and the third voltage with reference to FIG. 6 are described as follows, and may not be the same as the definitions of the first voltage, the second voltage and the third voltage with reference to FIG. 5.

Still taking the selected memory cell 450 as an example, at first, a first voltage is supplied to the bit-write line BLw(1) (step S600), and a second voltage is supplied to the plate line PL(1) (step S610). In the embodiment, the absolute value of the first voltage is slightly greater than the absolute value of the second voltage. For example, the absolute value of the first voltage is about 0.2V˜0.5V higher than the absolute value of the second voltage, but the actual difference depends on the ferroelectric material used in the FeFET 450 and is not limited to the above range. Then, a third voltage is supplied to the word line WL(1) (step S620), and the third voltage should be sufficient to switch on the non-ferroelectric FET 410. At last, a voltage level is acquired from the bit-read line BLr(1) (step S630), and this voltage level represents the data stored in the memory cell 450.

In this embodiment, all of the plate lines PL(1)˜PL(4), the bit-write lines BLw(2)˜BLw(4) not electrically connected to the selected memory cell 450 and the bit-read lines BLr(2)˜BLr(4) not electrically connected to the selected memory cell 450 may be biased to the second voltage (e.g. ⅓ Vpp or zero voltage) in advance. Besides, the word lines WL(2)˜WL(4) not electrically connected to the selected memory cell 450 are biased to an electric potential insufficient to switch on the non-ferroelectric FETs 410. Moreover, before the step S630, the bit-read line BLr(1) electrically connected to the selected memory cell 450 may be biased to a pre-charge voltage, wherein the absolute value of the pre-charge voltage is slightly higher than the absolute value of the second voltage.

It is to be noted that the absolute value of the second voltage in this embodiment is one third of the minimum among absolute values of voltage differences sufficient to program the FeFET. Or, the second voltage is zero.

Comparing the data writing method with the data reading method, it is found that, for switching between the data write operation and the data read operation, only the first voltage supplied to the bit-write line BLw(1) electrically connected to the selected memory cell 450 needs to be changed. Therefore, the data writing method and the data reading method of the ferroelectric memory according to the disclosure can effectively reduce power consumption and delay time during switching between data writing and data reading.

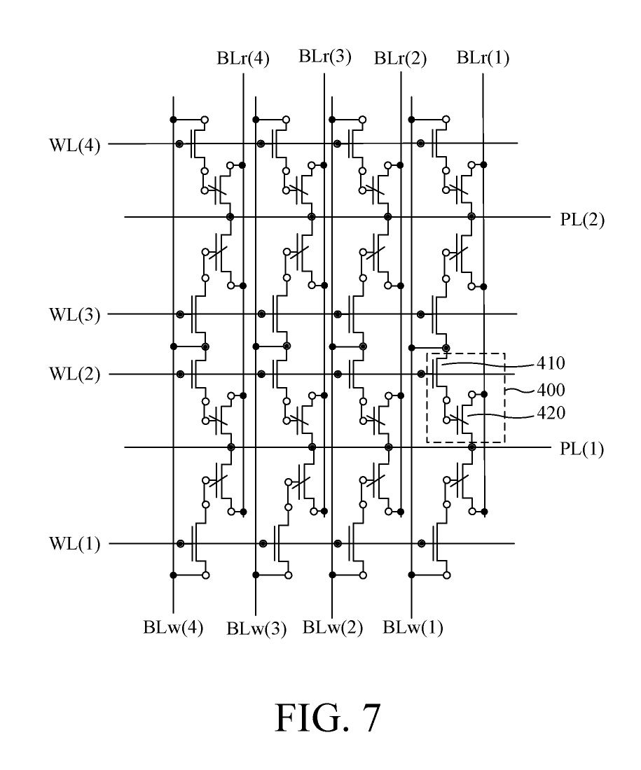

Moreover, the circuit layout of the aforementioned ferroelectric memory is not limited to that as shown in FIG. 4. Please refer to FIG. 7, a circuit diagram illustrating a portion of an array structure in a ferroelectric memory according to another embodiment of the disclosure. Comparing FIG. 7 with FIG. 4, the distinction is that dispositions of the word lines, the plate lines, the bit-read lines and the bit-write lines are different. Due to different dispositions of the lines, the number of the plate lines in the embodiment of FIG. 7 is fewer than that of FIG. 4, which further benefits production cost reduction. Except for the distinction, interconnections among the internal components, the word lines, the plate lines, the bit-read lines and the bit-write lines in the memory cell 400 according to the embodiment in FIG. 7 are similar to those described in FIG. 4. In addition, the data writing method and the data reading method of the ferroelectric memory in FIG. 7 are similar to those described in FIG. 5 and FIG. 6. Thus, repetitious details are not given here.

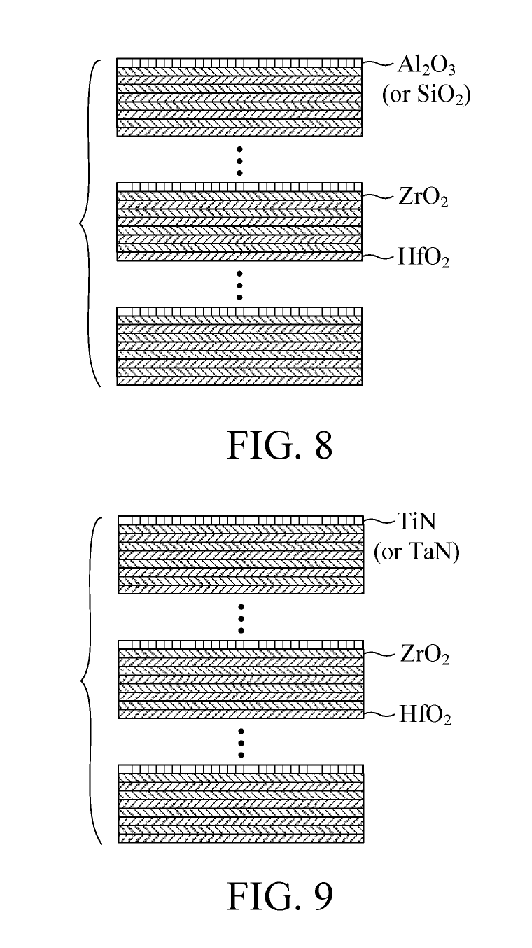

The composition of the ferroelectric layer is given now. Please refer to FIG. 8, a schematic diagram illustrating the composition of the ferroelectric layer according to an embodiment of the disclosure. For example, the ferroelectric layer of the FeFET is made of a HfₓZr₍₁₋ₓ₎O_{y} ferroelectric material doped with Al or Si, wherein the doping concentration ranges from 1% to 15%, preferably from 1% to 5%. The ferroelectric layer is formed by atomic layer deposition (ALD). HfO₂ and zirconium dioxide (ZrO₂) in the form of single atomic film are grown layer by layer repeatedly or alternately. By controlling the number of the HfO₂ films and the ZrO₂ films in each process cycle, the x value and the y value can be adjusted. For example, the x value ranges from 0.25 to 0.75, preferably from 0.4 to 0.6; and the y value ranges from 1.8 to 2.2, preferably from 1.9 to 2.1. By means of this manufacturing method, the thickness of the ferroelectric layer in the FeFET of the ferroelectric memory can be reduced to a range from 5 nm to 30 nm, even 5 nm to 15 nm.

In the embodiment of FIG. 8, the ratio of the number of the HfO₂ films to the number of the ZrO₂ films is 1:1. That is, the HfO₂ films and the ZrO₂ films are alternately deposited. One HfO₂ film and one ZrO₂ film constitute a process cycle, and the HfO₂ film and the ZrO₂ film are not limited as a top layer and a lower layer or as a lower layer and a top layer. In the meantime, the x value is 0.5 and the y value is 2. If the ratio of the number of the HfO₂ film(s) in each process cycle increases, the x value is greater than 0.5. On the contrary, if the ratio of the number of the ZrO₂ film(s) in each process cycle increases, the x value is smaller than 0.5. After several process cycles, at least one Al₂O₃ film or at least one SiO₂ film may be formed. In this embodiment, one Al₂O₃ film or one SiO₂ film is inserted after every four process cycles by using the ALD method. Thus, the doping concentration of Al or Si is about 11%. When the number of cycles for stacking films is larger than ten, the doping concentration of Al or Si is smaller than 5%.

For forming the HfO₂ films, the ZrO₂ films, the Al₂O₃ films and/or the SiO₂ films, the oxidant may be ozone (O₃) or water (H₂O). The precursor for forming the HfO₂ films may be tetrakis(ethylmethylamino)hafnium (TEMAH), tetrakis(dimethylamino) hafnium (TDMAH) or hafnium tetrachloride (HfCl₄), and the deposition temperature (reaction temperature) ranges from 150° C. to 400° C. The precursor for forming the ZrO₂ films may be tetrakis(ethylmethylamino) zirconium (TEMAZ), tetrakis(dimethylamino) zirconium (TDMAZ) or zirconium(IV) chloride (ZrCl₄), and the deposition temperature (reaction temperature) ranges from 150° C. to 400° C. The precursor for forming the Al₂O₃ films may be trimethylaluminum (TMA) or aluminum chloride (AlCl₃), and the deposition temperature (reaction temperature) ranges from 150° C. to 400° C. The precursor for forming the SiO₂ films may be tetrakis(dimethylamino)silane (4DMAS), tris(dimethylamino)silane (3DMAS), silicon tetrachloride (SiCl₄) or tetrakis(ethylmethylamino) silane (TEMA-Si), and the deposition temperature (reaction temperature) ranges from 150° C. to 400° C.

By this manufacturing method, the ferroelectric layer has more stable characteristics because the precision of the ALD method can be controlled at an atomic level. In addition, the ferroelectric layer also has the property of being conformal, so that doping concentration variation, thickness variation, temperature variation and stress variation, which are common in fabrication processes of a large size wafer, will have better tolerance.

The dopants Al or Si in the above embodiments may be replaced by Ti or Ta to adjust or reduce the coercive field (Ec). Please refer to FIG. 9, a schematic diagram illustrating the composition of the ferroelectric layer according to another embodiment of the disclosure. For example, the ferroelectric layer of the FeFET is made of a HfₓZr₍₁₋ₓ₎O_{y} ferroelectric material doped with Ti or Ta, wherein the doping concentration ranges from 1% to 15%, preferably from 1% to 5%. The ferroelectric layer is formed by ALD. HfO₂ and ZrO₂ in the form of single atomic films are grown layer by layer repeatedly or alternately. By controlling the number of the HfO₂ films and the ZrO₂ films in each process cycle, the x value and the y value can be adjusted. For example, the x value ranges from 0.25 to 0.75, preferably from 0.4 to 0.6; and the y value ranges from 1.8 to 2.2, preferably from 1.9 to 2.1. By means of this manufacturing method, when the ferroelectric material is implemented into the FeFET in the ferroelectric memory, the thickness of the ferroelectric layer can be reduced to a range from 5 nm to 30 nm, even 5 nm to 15 nm.

In the embodiment of FIG. 9, the ratio of the number of the HfO₂ films to the number of the ZrO₂ films is 1:1. That is, the HfO₂ films and the ZrO₂ films are alternately deposited. One HfO₂ film and one ZrO₂ film constitute a process cycle, and the HfO₂ film and the ZrO₂ film are not limited as a top layer and a lower layer or as a lower layer and a top layer. In the meantime, the x value is 0.5 and the y value is 2. If the ratio of the number of the HfO₂ film(s) in each process cycle increases, the x value is greater than 0.5. On the contrary, if the ratio of the number of the ZrO₂ film(s) in each process cycle increases, the x value is smaller than 0.5. After several process cycles, at least one TiN film or at least one TaN film may be formed. In this embodiment, one TiN film or one TaN film is inserted after every four process cycles. Thus, the doping concentration of Ti or Ta is about 11%. When the number of cycles for stacking films is larger than ten, the doping concentration of Ti or Ta is smaller than 5%.

For forming the HfO₂ films and the ZrO₂ films, the oxidant may be O₃ or H₂O, and the precursors and deposition temperature (reaction temperature) may refer to the above embodiments. For forming the TiN films or the TaN films, the nitrogen donating medium may be ammonia (NH₃). The precursor for forming the TiN films may be titanium tetrachloride (TiCl₄) or tetrakis(diethylamino)titanium (TDEAT), and the deposition temperature (reaction temperature) ranges from 200° C. to 500° C. The precursor for forming the TaN films may be tantalum(V) chloride (TaCl₅), tantalum(V) fluoride (TaF₅) or tantalum(V) bromide (TaBr₅), and the deposition temperature (reaction temperature) ranges from 200° C. to 500° C. By this manufacturing method, the ferroelectric layer identically has the advantage of being of stable characteristics.

Besides, the ferroelectric layer may be made of a Hf_{0.8}Si_{0.2x}Zr₍₁₋ₓ₎O_{y} ferroelectric material. First, by ALD, the Hf_{0.8}Si_{0.2}O₂ film containing 20% Si is formed. The precursor for donating Hf may be TEMAH, TDMAH or HfCl₄; the precursor for donating Si may be 4DMAS, 3DMAS, SiCl₄ or TEMA-Si; the oxidant may be O₃ or H₂O; and the deposition temperature (reaction temperature) ranges from 300° C. to 400° C. Then, using ALD to deposit Hf_{0.8}Si_{0.2}O₂ films and the ZrO₂ films according to a specific ratio so as to form Hf_{0.8x}Si_{0.2x}Zr₍₁₋ₓ₎O_{y} The precursor may be TEMAZ, TDMAZ or ZrCl₄, and the deposition temperature (reaction temperature) ranges from 300° C. to 400° C. By controlling the number of the Hf_{0.8}Si_{0.2}O₂ films and the ZrO₂ films in each process cycle, the x value and the y value can be adjusted. For example, the x value ranges from 0.25 to 0.75, preferably from 0.4 to 0.6; and the y value ranges from 1.8 to 2.2, preferably from 1.9 to 2.1. By means of this manufacturing method, when the ferroelectric material is implemented into the FeFET in the ferroelectric memory, the thickness of the ferroelectric layer can be reduced to a range from 5 nm to 30 nm, even 5 nm to 15 nm.

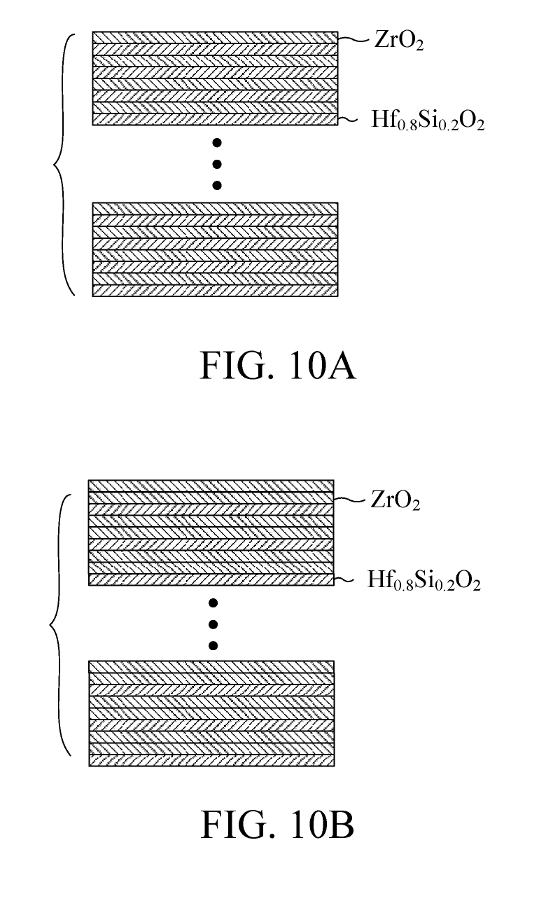

In the embodiment of FIG. 10A, the ratio of the number of the Hf_{0.8}Si_{0.2}O₂ films to the number of the ZrO₂ films is 1:1. That is, the Hf_{0.8}Si_{0.2}O₂ films and the ZrO₂ films are alternately deposited. One Hf_{0.8}Si_{0.2}O₂ film and one ZrO₂ film constitute a process cycle, and the Hf_{0.8}Si_{0.2}O₂ film and the ZrO₂ film are not limited as a top layer and a lower layer or as a lower layer and a top layer In this case, the x value is 0.5 and the y value is 2, and the doping concentration of Si is 10%. If the ratio of the number of the Hf_{0.8}Si_{0.2}O₂ film(s) in each process cycle increases, the x value is greater than 0.5, and the doping concentration of Si is greater than 10%. On the contrary, if the ratio of the number of the ZrO₂ film(s) in each process cycle increases, the x value is smaller than 0.5, and the doping concentration of Si is smaller than 10%. In the embodiment of FIG. 10B, the ratio of the number of the Hf_{0.8}Si_{0.2}O₂ films to the number of the ZrO₂ films is 1:2. And in that case, the x value is 0.33 and the y value is 2, and the doping concentration of Si is 6.6%. The Si component can adjust or increase the coercive field.

In addition, the ferroelectric layer may be made of a Hf_{0.9x}Si_{0.1x}Zr₍₁₋ₓ₎O_{y} ferroelectric material or a Hf_{0.95x}Si_{0.05x}Zr₍₁₋ₓ₎O_{y} ferroelectric material. The manufacturing method may be modified with reference to FIG. 10A and FIG. 10B, and repetitious details are not given here.

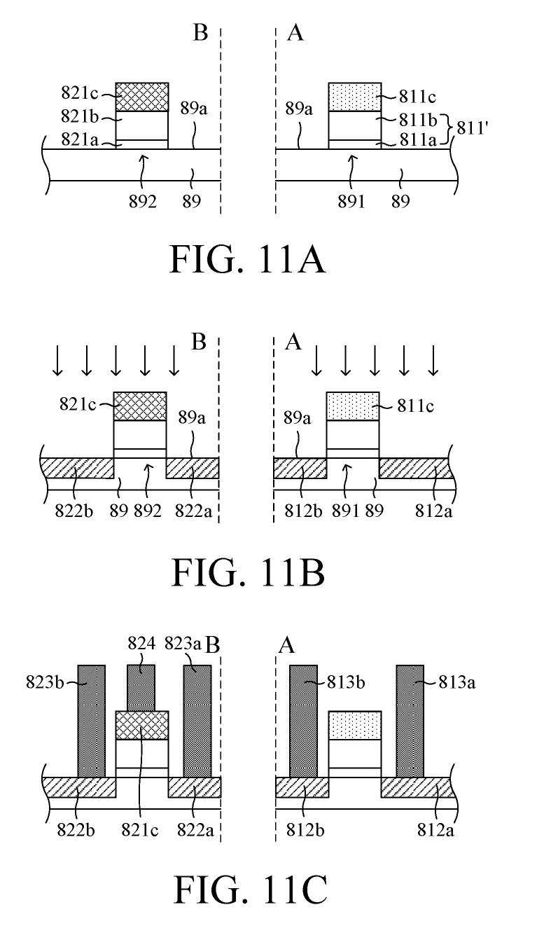

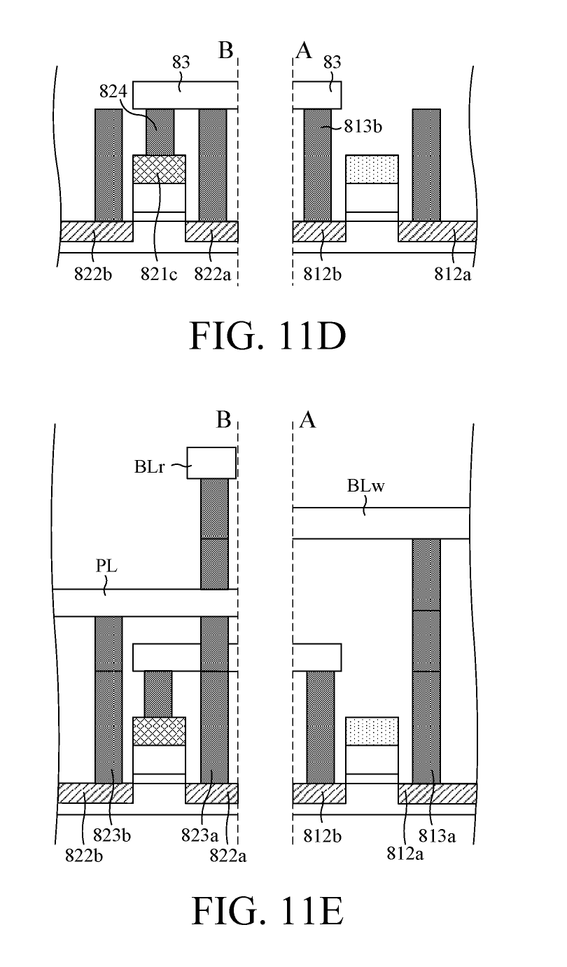

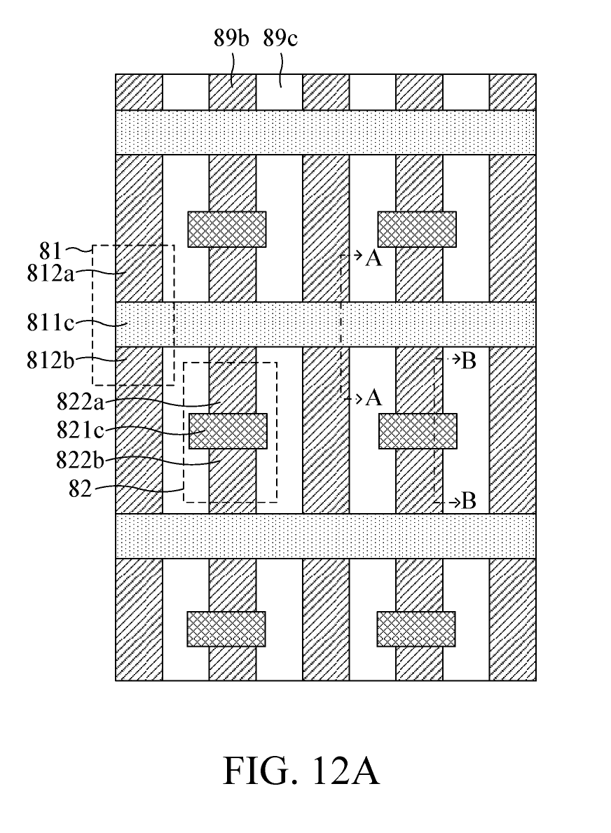

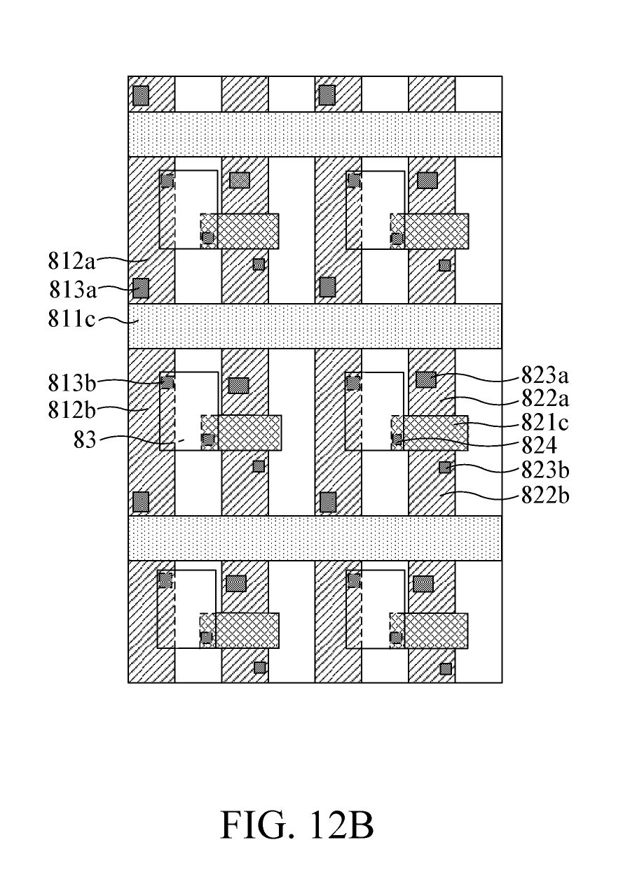

A manufacturing method of the ferroelectric memory of FIG. 4 is recited as below. Please refer to FIG. 11A˜FIG. 11E, schematic diagrams illustrating a manufacturing method of a ferroelectric memory according an embodiment of the disclosure. Only one ferroelectric memory cell is shown in the drawings, but the ferroelectric memory actually includes an array of ferroelectric memory cells. In the drawings, a non-ferroelectric FET will be formed in the region A, and a FeFET will be formed in the region B. It is to be noted that the cross-sections of the region A and the region B are not coplanar. For example, referring to the top view of FIG. 12A, the region A shown in any of FIGS. 11A˜11E is a side view which is viewed from the line A-A to the left, the region B shown in any of FIGS. 11A˜11E is a side view which is viewed from the line B-B to the left, and the column direction and the row direction identified in the embodiments should be based on FIGS. 12A and 12B.

As shown in FIG. 11A, at first, a semiconductor substrate 89 is provided. The semiconductor substrate 89 may be made of a known semiconductor material, e.g. Si. Shallow trench isolation (STI) is used to dispose one or more dielectric materials (e.g. SiO₂) in trenches to form isolation regions 89c (as shown in FIG. 12A) in the semiconductor substrate 89 to isolate and define active areas 89b where the non-ferroelectric FETs and FeFETs will be formed. The region A and the region B correspond to the active areas 89b, and the active areas 89b may be optionally doped with a material of a first conductivity type.

Then, a first dielectric layer 811′ and a word line 811c are formed and stacked on an upper surface 89a of the first area 891 of the semiconductor substrate 89 in the region A. The first dielectric layer 811′ optionally includes a gate dielectric layer 811a and a high-k dielectric layer 811b. This step may include sub-steps of: sequentially depositing an insulating layer (e.g. made of SiO₂ or SiON) and/or a high-k dielectric film and an electrode layer (e.g. made of TiN, TaN, WN, W, Ir, Ru, RuOₓ, Pt, Pd or other conductive material); and patterning the stacked deposition layers with a hard shield to remain deposition layers on the first area 891 of the semiconductor substrate 89 and form the gate dielectric layer 811a and/or the high-k dielectric layer 811b and the word line 811c. It is to be noted that the disclosure is not limited to the sub-steps. The shield may also be called as a mask or a mask plate. In the array structure, the ferroelectric memory cells in the same row (FIG. 12A) connect to a common word line 811c. In other words, the word line 811c extends along the row direction.

Furthermore, a second dielectric layer 821a, a polarity retention layer 821b and a control electrode 821c are formed and stacked on the upper surface 89a of the second area 892 of the semiconductor substrate 89 in the region B. This step may include sub-steps of: sequentially depositing an insulating layer (e.g. made of SiO₂ or SiON), a ferroelectric layer (e.g. made of known ferroelectric materials or the combination of the above-described ferroelectric layer and anti-ferroelectric layer) and an electrode layer (e.g. made of TiN, TaN, WN, W, Ir, Ru, RuOₓ, Pt, Pd or other conductive material); annealing at a temperature ranging from 450° C. to 1000° C.; and patterning the stacked deposition layers with a hard shield to remain deposition layers on the second area 892 of the semiconductor substrate 89 and form the second dielectric layer 821a, the polarity retention layer 821b and the control electrode 821c. To facilitate etching, the etching process may be performed by using boron trichloride (BCl₃) and chlorine (Cl₂) in a high temperature chamber with chucks.

The disclosure does not limit the sequence of forming the word line 811c in the region A and the control electrode 821c in the region B. The sequence may be adjusted according to process demand or degree of difficulty. The polarity retention layer 821b may further include the charge blocking layer as described with reference to FIG. 3A, and the charge blocking layer is disposed between the anti-ferroelectric layer and the ferroelectric layer. The charge blocking layer may be made of SiO₂, Si₃N₄, Al₂O₃, HfO₂ or ONO. The relative positions of the ferroelectric layer, the anti-ferroelectric layer and/or the charge blocking layer in the polarity retention layer 821b may be arranged as those described with reference to FIG. 2A, FIG. 2B, FIG. 3A or FIG. 3B.

Subsequently, as shown in FIG. 11B, a source/drain doping step is performed by using the word line 811c and the control electrode 821c as a mask. Doping of a material of the second conductivity type is performed on the upper surface 89a of the semiconductor substrate 89. The first conductivity type is different from the second conductivity type. For example, if the material of the first conductivity type is a p-type dopant, the material of the second conductivity type is an n-type dopant, and vice verse. In this embodiment, the n-type dopant used in the source/drain doping step may be, for example, arsenic (As) or phosphorus (P), and the doping concentration ranges from 5×10¹⁹ cm⁻³ to 2×10²¹ cm⁻³. Thus, in the active area 89b of the semiconductor substrate 89, a first doped region 812a and a second doped region 812b are formed in the vicinity of the first area 891 and near the upper surface 89a of the semiconductor substrate 89, while a third doped region 822a and a fourth doped region 822b are formed in the vicinity of the second area 892 and near the upper surface 89a of the semiconductor substrate 89. A high temperature annealing step may be performed at a temperature ranging from 850° C. to 1050° C. to active the dopants in the doped regions. The doped regions in the drawings do not extend to the semiconductor substrate 89 underneath the dielectric layers. However, it is applicable to use tilt-doping or thermal diffusion to extend the doped regions to the semiconductor substrate 89 underneath the dielectric layers. In the case, the top view of the resultant array structure is as shown in FIG. 12A. The non-ferroelectric FET 81 includes the first dielectric layer 811′, the word line 811c, the first doped region 812a, the second doped region 812b and the first area 891 of the semiconductor substrate 89; and the FeFET 82 includes the second dielectric layer 821a, the polarity retention layer 821b, the control electrode 821c, the third doped region 822a, the fourth doped region 822b and the second area 892 of the semiconductor substrate 89.

Then, as shown in FIG. 11C, a first interconnect 813a, a second interconnect 813b, a third interconnect 823a, a fourth interconnect 823b and an electrode interconnect 824 are formed on and electrically connected to the first doped region 812a, the second doped region 812b, the third doped region 822a, the fourth doped region 822b and the control electrode 821c, respectively. The interconnects may be formed separately, concurrently, or partially concurrently. The disclosure does not limit the order of forming the interconnects, and one may make a plan in consideration of the process requirement, the minimal production cost or the shortest production time.

Subsequently, as shown in FIG. 11D, a plate 83 is formed to electrically connect the electrode interconnect 824 and the second interconnect 813b. The top view of the resultant array structure is as shown in FIG. 12B. It is to be noted that the plate 83 is not in contact with the third interconnect 823a.

At last, as shown in FIG. 11E, a plate line PL, a bit-write line BLw and a bit-read line BLr are formed to electrically connect the fourth interconnect 823b, the first interconnect 813a, and the third interconnect 823a, respectively. The ferroelectric memory cells in the same column connect to a common plate line PL. That is, the plate line PL extends along the column direction. The ferroelectric memory cells in the same column connect to a common bit-write line BLw. That is, the bit-write line BLw extends along the column direction. The ferroelectric memory cells in the same row connect to a common bit-read line BLr. That is, the bit-read line BLr extends along the row direction. Thus, the ferroelectric memory having the array structure as shown in FIG. 4 is finished. After that, associated processes of back-end-of-line (BEOL) can be performed.

In the array structure, in order that the plate 83, the plate line PL, the bit-write line BLw and the bit-read line BLr can be staggered, the plate and the lines are arranged at different heights in the embodiment. For example, the position of the bit-read line BLr is higher than the position of the bit-write line BLw, the position of the bit-write line BLw is higher than the position of the plate line PL, and the position of the plate line PL is higher than the position of the plate 83. To make electrical connections, it needs to correspondingly padding the height of the specific interconnect in each manufacturing process, but the disclosure does not limit the arrangement order of the heights of the interconnects. It is also possible to adjust corresponding heights and forming sequence of the plate 83, the plate line PL, the bit-write line BLw and the bit-read line BLr according to a manufacturing plan. Parallel lines may be arranged at the same height and formed in the same step. Such modification is applicable to all embodiments of the disclosure.

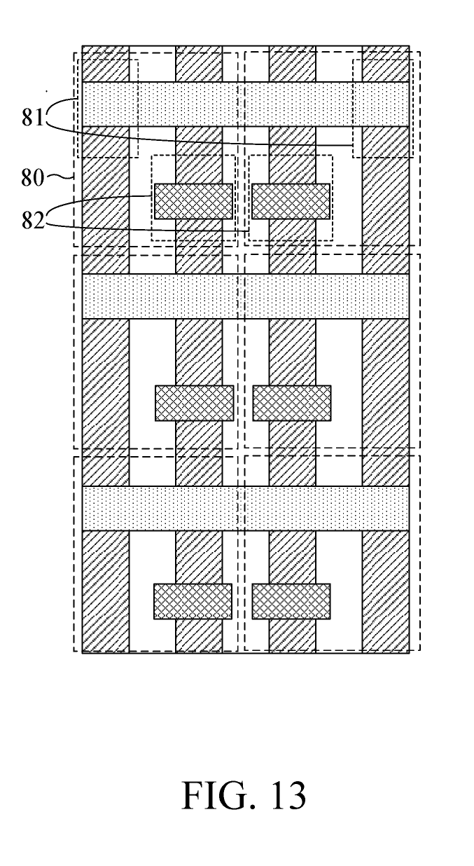

In the manufacturing method of the disclosure, the arrangement of the ferroelectric memory and the non-ferroelectric memory may be modified, such as shown in FIG. 12A, the structure of the ferroelectric memory is constituted by alternately arranging a column of the non-ferroelectric FETs 81 and a column of the FeFETs 82. Therefore, the relative position between the non-ferroelectric FET 81 and the FeFET 82 is identical within each of the ferroelectric memory cells. FIG. 13 shows another arrangement method, wherein positions of the FeFETs 82 are interchanged with those of the non-ferroelectric FET 81 in each of two adjacent columns of ferroelectric memory cells 80. Therefore, a memory cell 80 in a column is a mirror of another memory cell in an adjacent column. The manufacturing method of the ferroelectric memory is similar to that described with reference to FIG. 11A˜FIG. 11E, and repetitious details are not given here.

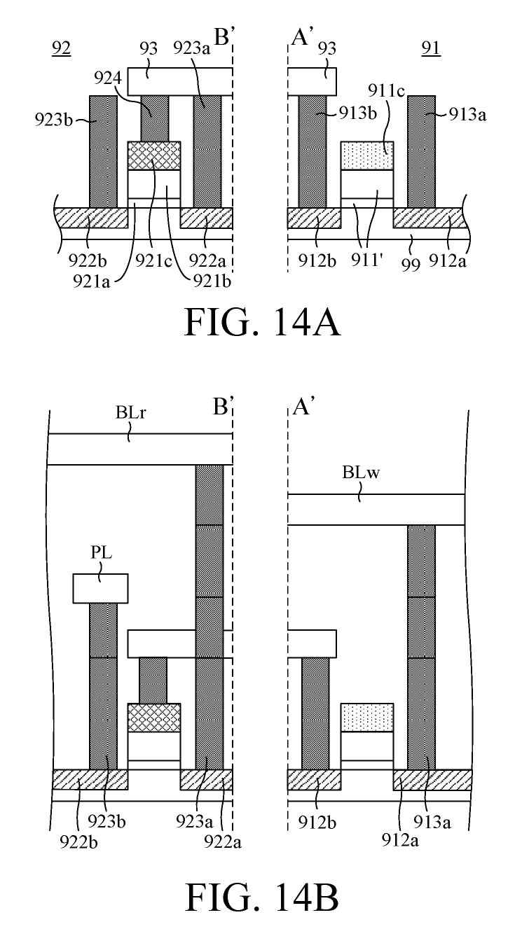

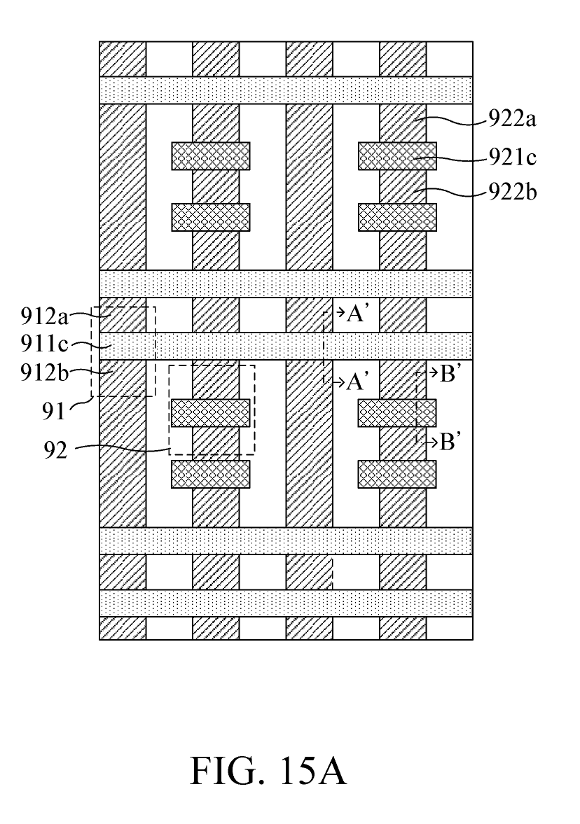

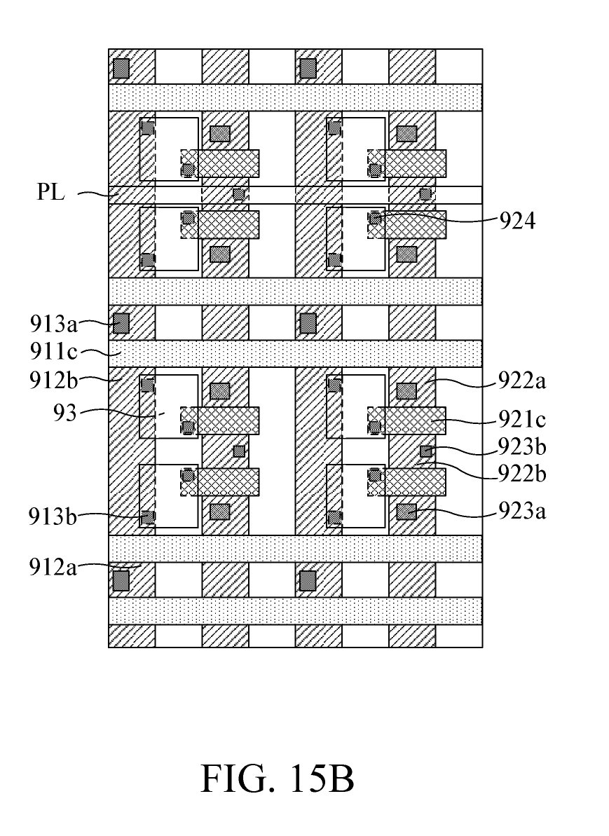

The ferroelectric memory having an array structure in FIG. 7 may be made by using a similar manufacturing method. The initial steps are similar to those in FIGS. 11A˜11C. That is, forming a word line, a first dielectric layer (gate dielectric layer and/or high-k dielectric layer), a second dielectric layer, a polarity retention layer, a control electrode, a first doped region, a second doped region, a third doped region, a fourth dope region, a first interconnect, a second interconnect, a third interconnect, a fourth interconnect and an electrode interconnect. The subsequent step is shown in FIG. 14A, the details are not given again. Please note that only one ferroelectric memory cell is shown in the figure, but the ferroelectric memory actually includes multiple ferroelectric memory cells arranged in an array. In the drawings, the non-ferroelectric FET will be formed in the region A′, and the FeFET will be formed in the region B′. It is to be noted that the cross-sections of the region A′ and the region B′ are not coplanar (as the top view shown in FIG. 15A). The region A′ shown in any of FIGS. 14A˜14B is a side view which is viewed from the line A′-A′ to the left, the region B′ shown in any of FIGS. 14A˜14B is a side view which is viewed from the line B′-B′ to the left, and the column direction and the row direction identified in the embodiments should be based on FIGS. 15A and 15B.

In the above embodiment with reference to FIG. 12A, viewing along the column direction, the word lines 811c and the control electrodes 821c are arranged alternately. In the embodiment of FIG. 15A, two word lines 911c and two control electrodes 921c are alternately arranged along the column direction. This kind of arrangement forms pairs of connected non-ferroelectric FETs 91 and pairs of connected FeFETs 92. In the structure, a non-ferroelectric FET 91 includes a first dielectric layer 911′, a word line 911c, a first doped region 912a, a second doped region 912b and the semiconductor substrate 99 between the doped regions 912a and 912b; and a FeFET 92 includes a second dielectric layer 921a, a polarity retention layer 921b, a control electrode 921c, a third doped region 922a, a fourth doped region 922b and the semiconductor substrate 99 between the doped regions 922a and 922b.

A first interconnect 913a, a second interconnect 913b, a third interconnect 923a, a fourth interconnect 923b and an electrode interconnect 924 are formed on and electrically connected to the first doped region 912a, the second doped region 912b, the third doped region 922a, the fourth doped region 922b and the control electrode 921c, respectively. Then, a plate 93 is formed to electrically connect the electrode interconnect 924 and the second interconnect 913b. It is to be noted that the plate 93 is not in contact with the third interconnect 923a. The resultant structure is shown in 14A.

At last, as shown in FIG. 14B, a plate line PL, a bit-write line BLw and a bit-read line BLr are formed to electrically connect the forth interconnect 923b, the first interconnect 913a, and the third interconnect 923a, respectively. The ferroelectric memory cells in the same row connect a common plate line PL. That is, the plate line PL extends along the row direction. The ferroelectric memory cells in the same column connect a common bit-write line BLw. That is, the bit-write line BLw extends along the column direction. The ferroelectric memory cells in the same column connect a common bit-read line BLr. That is, the bit-read line BLr extends along the column direction. Thus, the ferroelectric memory having the array structure as shown in FIG. 7 is finished. After that, associated processes of back-end-of-line (BEOL) can be performed.

Please refer to the top view in FIG. 15B. For clarity, the figure only shows one plate line PL, and other plate lines are omitted. It can be seen that the FeFETs at top and bottom sides of the plate line PL share this plate line PL. Therefore, fewer plate lines PL are required in this embodiment. It is advantageous to reduce production cost.

In the description, only the elements involved in electrical connections are described and shown. The space among the elements is filled with insulating material for isolation and protection. The insulating material may fill the space before or after any one of the above-described steps, and steps of depositing, patterning, etching and filling may be involved. These processes may be used and implemented in the disclosure without detailed description and are within scope of the application.

In the description, the column direction and the row direction are used to illustrate the array structure of the ferroelectric memory and are not used to limit the directions of the elements. The column direction and the row direction are interchangeable in the applications.

In conclusion, the disclosure provides specific ferroelectric materials and related manufacturing methods which can miniaturize the FeFETs. The manufacturing method provides better tolerance to doping concentration variation, thickness variation, temperature variation and stress variation. Furthermore, the data writing method and the data reading method according to the disclosure can enhance the operation speed and reliability of the ferroelectric memory.

While the disclosure has been described in terms of what is presently considered to be the most practical and preferred embodiments, it is to be understood that the invention needs not be limited to the disclosed embodiment. On the contrary, it is intended to cover various modifications and similar arrangements included within the spirit and scope of the appended claims which are to be accorded with the broadest interpretation so as to encompass all such modifications and similar structures.

What is claimed is:

1. A ferroelectric field effect transistor, comprising:
a semiconductor substrate having an upper surface, made of a semiconductor material, and doped with a material of a first conductivity type;
a first doped region formed in the semiconductor substrate and having a material of a second conductivity type;
a second doped region formed in the semiconductor substrate and having the material of the second conductivity type, the second doped region being separated from the first doped region;
a dielectric layer disposed on and in contact with the upper surface of the semiconductor substrate;
a polarity retention layer comprising a ferroelectric layer and an anti-ferroelectric layer, the polarity retention layer and the semiconductor substrate being disposed on opposite surfaces of the dielectric layer; and
a conductive layer, the dielectric layer and the conductive layer being disposed on opposite surfaces of the polarity retention layer.

2. The ferroelectric field effect transistor according to claim 1, wherein the anti-ferroelectric layer is disposed on and in contact with the dielectric layer, and the ferroelectric layer is disposed on and in contact with the anti-ferroelectric layer; or the ferroelectric layer is disposed on and in contact with the dielectric layer, and the anti-ferroelectric layer is disposed on and in contact with the ferroelectric layer.

3. The ferroelectric field effect transistor according to claim 1, wherein the polarity retention layer further comprises a charge blocking layer.

4. The ferroelectric field effect transistor according to claim 3, wherein the anti-ferroelectric layer is disposed on and in contact with the dielectric layer, the charge blocking layer is disposed on and in contact with the anti-ferroelectric layer, and the ferroelectric layer is disposed on and in contact with the charge blocking layer.

5. The ferroelectric field effect transistor according to claim 3, wherein the ferroelectric layer is disposed on and in contact with the dielectric layer, the anti-ferroelectric layer is disposed on and in contact with the ferroelectric layer, and the charge blocking layer is disposed on and in contact with the anti-ferroelectric layer.

6. A ferroelectric memory comprising a plurality of memory cells, each of the memory cells being electrically connected to a bit-write line, a bit-read line, a word line and a plate line, each of the memory cells comprising:
a non-ferroelectric field effect transistor comprising a non-ferroelectric control terminal, a first non-ferroelectric access terminal and a second non-ferroelectric access terminal, the non-ferroelectric control terminal being electrically connected to the word line, the first non-ferroelectric access terminal being electrically connected to the bit-write line; and
a ferroelectric field effect transistor comprising a ferroelectric control terminal, a first ferroelectric access terminal and a second ferroelectric access terminal, the ferroelectric control terminal being electrically connected to the second non-ferroelectric access terminal, the first ferroelectric access terminal being electrically connected to the bit-read line, the second ferroelectric access terminal being electrically connected to the plate line.

7. A data writing method of a ferroelectric memory, adapted to be implemented in the ferroelectric memory of claim 6, comprising steps of:
supplying a first voltage to the bit-write line, the first voltage representing data to be stored;
supplying a second voltage to the bit-read line;
supplying the second voltage to the plate line; and
supplying a third voltage to the word line,
wherein the third voltage is sufficient to turn on the non-ferroelectric field effect transistor, and a difference between the first voltage and the second voltage is sufficient to program the ferroelectric field effect transistor.

8. The data writing method according to claim 7, wherein an absolute value of the second voltage is equal to one third of an absolute value of the difference sufficient to program the ferroelectric field effect transistor.

9. A data reading method of a ferroelectric memory, adapted to be implemented in the ferroelectric memory of claim 6, comprising steps of:
supplying a first voltage to the bit-write line;
supplying a second voltage to the plate line;
supplying a third voltage to the word line; and
acquiring a voltage level from the bit-read line for serving as data stored in the memory cell,
wherein the third voltage is sufficient to turn on the non-ferroelectric field effect transistor, and an absolute value of the first voltage is greater than an absolute value of the second voltage.

10. The data reading method according to claim 9, wherein the second voltage is a default voltage, and an absolute value of the default voltage is equal to one third of an absolute value of the difference sufficient to program the ferroelectric field effect transistor.

11. The data reading method according to claim 9, further comprising a step of biasing the bit-read line to a pre-charge voltage prior to the step of supplying the third voltage to the word line, wherein an absolute value of the pre-charge voltage is greater than the absolute value of the second voltage.

12. A manufacturing method of a ferroelectric memory including a non-ferroelectric field effect transistor and a ferroelectric field effect transistor, comprising steps of:
providing a semiconductor substrate made of a semiconductor material and doped with a material of a first conductivity type;
forming a first dielectric layer and a word line on a first area of the semiconductor substrate;
forming a second dielectric layer, a polarity retention layer and a control electrode on a second area of the semiconductor substrate;
doping a material of a second conductivity type into the semiconductor substrate by using the word line and the control electrode as a mask to form a first doped region, a second doped region, a third doped region and a fourth region, the first doped region and the second doped region being adjacent to the first area, the third doped region and the fourth doped region being adjacent to the second area, wherein the non-ferroelectric field effect transistor comprises the first dielectric layer, the word line, the first doped region, the second doped region and the first area of the semiconductor substrate, and the ferroelectric field effect transistor comprises the second dielectric layer, the polarity retention layer, the control electrode, the third doped region, the fourth doped region and the second area of the semiconductor substrate;
forming a first interconnect, a second interconnect, a third interconnect, a fourth interconnect and an electrode interconnect respectively on the first doped region, the second doped region, the third doped region, the fourth doped region and the control electrode;
forming a plate electrically connected to the electrode interconnect and the second interconnect;
forming a plate line electrically connected to the fourth interconnect;
forming a bit-write line electrically connected to the first interconnect; and
forming a bit-read line electrically connected to the third interconnect.

13. The manufacturing method according to claim 12, wherein the polarity retention layer comprises a ferroelectric layer and an anti-ferroelectric layer.

14. The manufacturing method according to claim 13, wherein the step of forming the polarity retention layer further comprises steps of:
forming one of the anti-ferroelectric layer and the ferroelectric layer on the second dielectric layer; and
forming the other of the anti-ferroelectric layer and the ferroelectric layer on the one of the anti-ferroelectric layer and the ferroelectric layer.

15. The manufacturing method according to claim 13, wherein the polarity retention layer further comprises a charge blocking layer.

16. The manufacturing method according to claim 15, wherein the step of forming the polarity retention layer further comprises steps of:
forming the anti-ferroelectric layer on the second dielectric layer;
forming the charge blocking layer on the anti-ferroelectric layer; and
forming the ferroelectric layer on the charge blocking layer.

17. The manufacturing method according to claim 15, wherein the step of forming the polarity retention layer further comprises steps of:
forming the ferroelectric layer on the second dielectric layer;
forming the anti-ferroelectric layer on the ferroelectric layer; and
forming the charge blocking layer on the anti-ferroelectric layer.
